(19) United States
(12) Patent Application Publication
(10) Pub. No.: US 2026/0186666 A1
(43) Pub. Date: Jul. 2, 2026

(54) BUFFER CHIP, A MEMORY SYSTEM INCLUDING THE BUFFER CHIP AND A METHOD FOR OPERATING THE MEMORY SYSTEM

(71) Applicant: Samsung Electronics Co., Ltd., Suwon-si (KR)

(72) Inventors: Jichull Jeong, Suwon-si (KR); Yongjin Kim, Suwon-si (KR); Seungjin Park, Suwon-si (KR); Doobock Lee, Suwon-si (KR); Seunghoon Lee, Suwon-si (KR); Eunsang Lee, Suwon-si (KR)

(21) Appl. No.: 19/236,585

(22) Filed: Jun. 12, 2025

(30) Foreign Application Priority Data
Dec. 31, 2024 (KR) 10-2024-0202592

(51) Int. Cl. G06F 3/06; G11C 16/04; G11C 16/32; H03K 5/00; H03K 5/131

(52) U.S. Cl. CPC G06F 3/0614; G06F 3/0656; G06F 3/0679; G11C 16/32; H03K 5/131; G11C 16/0483; H03K 2005/00058

(57) ABSTRACT

A buffer chip that is connected between a memory controller and a memory device includes a first delay circuit and a second delay circuit. The first delay circuit is configured to delay a data signal based on a timing training operation that is performed by the memory controller between the buffer chip and the memory device. The second delay circuit is configured to delay a data strobe signal based on the timing training operation.

### CROSS-REFERENCE TO RELATED APPLICATION

This application claims priority to and the benefit of Korean Patent Application No. 10-2024-0202592 filed with the Korean Intellectual Property Office on Dec. 31, 2024, the entire contents of which are incorporated herein by reference.

### BACKGROUND

Memory systems may continue to evolve to support increasing performance and complexity. As memory system architectures become more advanced, various components may be used to manage data communication. Different configurations may be used depending on the design of the memory system.

### SUMMARY

In some cases, memory devices may transmit and receive data using a data strobe signal that has the same period as the clock. For example, the memory device can receive data transmitted from the memory controller in response to a data strobe signal during a write operation, and may transmit data to the memory controller in synchronization with the data strobe signal during a read operation.

To improve the operational reliability of the memory device, it may be desired to control the timing between the data signal and the data strobe signal. However, as memory devices become larger in capacity and faster, the number of cases where the timing between the data signal and the data strobe signal may be misaligned due to various factors, i.e.. skew, is increasing. Accordingly, various methods may be introduced to prevent the occurrence of skew by aligning signals between the memory controller and the memory device.

For example, a buffer chip, such as an FBI (Frequency Boosting Interface chip), may be configured between the memory controller and the memory device. The buffer chip may send and receive data and commands between the memory controller and the memory device. In this configuration of a memory controller-buffer chip-memory device, a training method may be used not only for aligning the timing of signals transmitted and received between the memory controller and the buffer chip, but also for aligning the timing of signals transmitted and received between the buffer chip and the memory device.

Implementations according to the present disclosure address issues such as those described above. Moreover, the issues to be addressed by the present disclosure is not limited to the above-mentioned issues, and other issues not explicitly stated will be clearly understood by those skilled in the art from the descriptions below.

In an aspect, implementations of the present disclosure relates to a buffer chip, a memory system including the buffer chip, and a method of operating the memory system, which can provide improved SI (Signal Integrity) by performing timing training operations between the buffer chip and a memory device as well as timing training operations between a memory controller and the buffer chip.

An aspect of the present disclosure provides a buffer chip that can be connected between a memory controller and a memory device, and that can include a first delay circuit configured to delay a data signal based on a timing training operation between the buffer chip and the memory device by the memory controller, and a second delay circuit configured to delay a data strobe signal based on a timing training operation between the buffer chip and the memory device by the memory controller.

Another aspect of the present disclosure provides a memory system that can include a memory device, a memory controller configured to output a data signal and a data strobe signal, and a buffer chip connected between the memory controller and the memory device. The memory controller can be configured to control a training operation for the buffer chip so that the data signal and the data strobe signal transmitted from the memory controller to the buffer chip are aligned, and the data signal and the data strobe signal transmitted from the buffer chip to the memory device are aligned.

Another aspect of the present disclosure provides a method of operating a memory system including a memory controller, a buffer chip, and a memory device. The method can include: performing a timing training operation on a data signal and a data strobe signal transmitted from the memory controller to the buffer chip by the memory controller; and performing a timing training operation on a data signal and a data strobe signal transmitted from the buffer chip to the memory device by the memory controller, based on a delay time of the data strobe signal in the buffer chip and a delay time of the data strobe signal in the memory device.

### BRIEF DESCRIPTION OF THE DRAWINGS

FIG. 1 is a diagram of an example of a memory system.

FIG. 2 is a diagram of an example of a memory system.

FIG. 3 is a diagram illustrating an example of tDQS2DQ.

FIG. 4 is a diagram illustrating an example of tDQS2DQ.

FIG. 5 is a diagram illustrating an example of an operation of a memory system.

FIG. 6 is a diagram illustrating an example of an operation of a memory system.

FIG. 7 is a diagram illustrating an example of an operation of a memory system.

FIG. 8 is a diagram illustrating an example of an operation of a memory system.

FIG. 9 is a diagram illustrating an example of an operation of a memory system.

FIG. 10 is a diagram illustrating an example of an operation of a memory system.

FIG. 11 is a diagram illustrating an example of an operation of a memory system.

FIG. 12 is a diagram illustrating an example of an operation of a memory system.

FIG. 13 is a diagram illustrating an example of an operation of a memory system.

FIG. 14 is a diagram illustrating an example of an operation of a memory system.

FIG. 15 is a diagram illustrating an example of an operation of a memory system.

FIG. 16 is a diagram illustrating an example of an operation of a memory system.

FIG. 17 is a diagram illustrating an example of a memory device.

FIG. 18 is a diagram illustrating an example of one memory block among a plurality of memory blocks included in a memory cell array.

FIG. 19 is a diagram illustrating an example of a memory system.

FIG. 20 is a diagram illustrating an example of a memory system.

FIG. 21 is a diagram illustrating an example of a memory system.

FIG. 22 is a diagram illustrating an example of a mobile system to which an example of a memory system is applied.

FIG. 23 is a diagram illustrating an example of a computing device to which an example of a memory system is applied.

FIG. 24 is a diagram illustrating an example of a system to which an example of a memory system is applied.

FIG. 25 is a diagram illustrating an example of a data center to which an example of a memory system is applied.

### DETAILED DESCRIPTION

Hereinafter, the present disclosure will be described in more detail through examples. These examples are just for illustrating the present disclosure, and the right protection scope of the present disclosure is not limited by the examples.

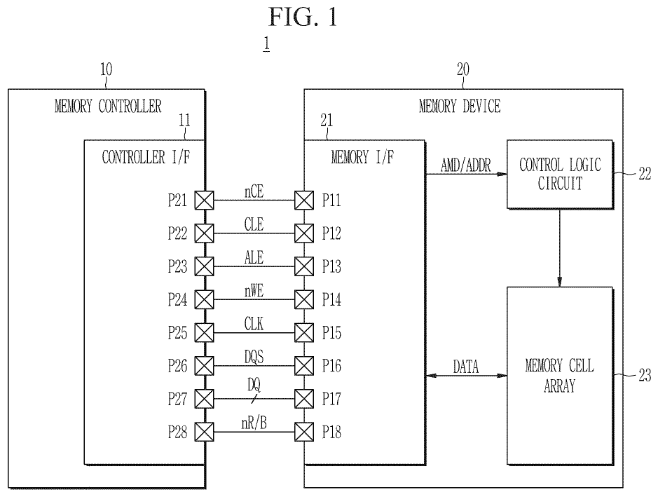

FIG. 1 is a block diagram of an example of a memory system.

Referring to FIG. 1, a memory system 1 can include a memory controller 10 and a memory device 20. The memory device 20 can include first to eighth pins P11 to P18, a memory interface 21, a control logic circuit 22, and a memory cell array 23.

The memory interface 21 can receive a chip enable signal nCE from the memory controller 10 through the first pin P11. The memory interface 21 can transmit and receive signals with the memory controller 10 through the second to eighth pins P12 to P18 according to the chip enable signal nCE. For example, when the chip enable signal nCE is in an enabled state e.g., low level, the memory interface 21 can transmit and receive signals with the memory controller 10 through the second to eighth pins P12 to P18.

The memory interface 21 can receive a command latch enable signal CLE, an address latch enable signal ALE, and a write enable signal nWE from the memory controller 10 through the second to fourth pins P12 to P14. The memory interface 21 can receive a data signal DQ from the memory controller 10 through the 7th pin P17 or transmit a data signal DQ to the memory controller 10. Commands CMD, addresses ADDR, and data DATA can be transmitted via data signals DQ.

For example, a data signal DQ can be transmitted over multiple data signal lines. In this case, the seventh pin P17 can include multiple pins corresponding to multiple data signals DQ.

The memory interface 21 can obtain a command CMD from a data signal DQ received in an enable period e.g., high level state of a command latch enable signal CLE based on the toggle timings of a write enable signal nWE. The memory interface 21 can obtain an address ADDR from a data signal DQ received in an enable period e.g., high level state of an address latch enable signal ALE based on the toggle timings of a write enable signal nWE.

In some implementations, the write enable signal nWE can remain in a static state e.g., a high level or a low level and toggle between the high level and the low level. For example, the write enable signal nWE can be toggled during a period where a command CMD or an address ADDR is transmitted. Accordingly, the memory interface 21 can obtain a command CMD or an address ADDR based on the toggle timings of the write enable signal nWE.

The memory interface 21 can receive a read enable signal nRE from the memory controller 10 through the fifth pin P15. The memory interface 21 can receive a data strobe signal DQS from the memory controller 10 through the sixth pin P16, or transmit a data strobe signal DQS to the memory controller 10.

In a data DATA output operation of a memory device 20, the memory interface 21 can receive a read enable signal nRE that toggles through the fifth pin P15 before outputting data DATA. The memory interface 21 can generate a data strobe signal DQS that toggles based on the toggling of the read enable signal nRE. For example, the memory interface 21 can generate a data strobe signal DQS that starts to toggle after a predetermined delay e.g., tDQSRE based on the toggling start time of the read enable signal nRE. The memory interface 21 can transmit a data signal DQ including data DATA based on the toggle timing of a data strobe signal DQS. Accordingly, data DATA can be transmitted to the memory controller 10 aligned with the toggle timing of the data strobe signal DQS.

In a data DATA input operation of a memory device 20, when a data signal DQ including data DATA is received from a memory controller 10, the memory interface 21 can receive a data strobe signal DQS that toggles together with the data DATA from the memory controller 10. The memory interface 21 can obtain data DATA from the data signal DQ based on the toggle timing of the data strobe signal DQS. For example, the memory interface 21 can obtain data DATA by sampling the data signal DQ at the rising edge and falling edge of the data strobe signal DQS.

The memory interface 21 can transmit a ready/busy output signal nR/B to the memory controller 10 through the 8th pin P18. The memory interface 21 can transmit status information of the memory device 20 to the memory controller 10 through a ready/busy output signal nR/B. When the memory device 20 is in a busy state i.e., when internal operations of the memory device 20 are being performed, the memory interface 21 can transmit a ready/busy output signal nR/B indicating the busy state to the memory controller 10. When the memory device 20 is in a ready state i.e., when internal operations of the memory device 20 are not performed or completed, the memory interface 21 can transmit a ready/busy output signal nR/B indicating the ready state to the memory controller 10. For example, while the memory device 20 reads data DATA from the memory cell array 23 in response to a page read command, the memory interface 21 can transmit a ready/busy output signal nR/B indicating a busy state e.g., low level to the memory controller 10. For example, while the memory device 20 programs data DATA into the memory cell array 23 in response to a program command, the memory interface 21 can transmit a ready/busy output signal nR/B indicating a busy state to the memory controller 10.

The control logic circuit 22 can control various operations of the memory device 20 in general. The control logic circuit 22 can receive a command/address CMD/ADDR obtained from the memory interface 21. The control logic circuit 22 can generate control signals for controlling other components of the memory device 20 according to the received command/address CMD/ADDR. For example, the control logic circuit 22 can generate various control signals for programming data DATA into the memory cell array 23 or reading data DATA from the memory cell array 23.

The memory cell array 23 can store data DATA obtained from the memory interface 21 under the control of the control logic circuit 22. The memory cell array 23 can output stored data DATA to the memory interface 21 under the control of the control logic circuit 22.

The memory cell array 23 can include a plurality of memory cells. For example, the plurality of memory cells can be flash memory cells. However, the present invention is not limited thereto, and the memory cells can be RRAM cells, FRAM cells, PRAM cells, TRAM Thyristor Random Access Memory cells, and MRAM cells. Below, the memory cells will be described as NAND flash memory cells.

The memory controller 10 can include first to eighth pins P21 to P28 and a controller interface 11. The first to eighth pins P21 to P28 can correspond to the first to eighth pins P11 to P18 of the memory device 20.

The controller interface 11 can transmit a chip enable signal nCE to the memory device 20 via the first pin P21. The controller interface 11 can transmit and receive signals through the second to eighth pins P22 to P28 and the selected memory device 20 via a chip enable signal nCE.

The controller interface 11 can transmit a command latch enable signal CLE, an address latch enable signal ALE, and a write enable signal nWE to the memory device 20 through the second to fourth pins P22 to P24. The controller interface 11 can transmit a data signal DQ to the memory device 20 or receive a data signal DQ from the memory device 20 via the seventh pin P27.

The controller interface 11 can transmit a data signal DQ including a command CMD or an address ADDR together with a toggling write enable signal nWE to the memory device 20. The controller interface 11 can transmit a data signal DQ including a command CMD to the memory device 20 by transmitting a command latch enable signal CLE having an enable state, and can transmit a data signal DQ including an address ADDR to the memory device 20 by transmitting an address latch enable signal ALE having an enable state.

The controller interface 11 can transmit a read enable signal nRE to the memory device 20 via the fifth pin P25. The controller interface 11 can receive a data strobe signal DQS from the memory device 20 or transmit a data strobe signal DQS to the memory device 20 via the sixth pin P26.

In a data DATA output operation of the memory device 20, the controller interface 11 can generate a toggling read enable signal nRE and transmit the read enable signal nRE to the memory device 20. For example, the controller interface 11 can generate a read enable signal nRE that changes from a fixed state e.g., a high level or a low level to a toggle state before data DATA is output. Accordingly, a data strobe signal DQS that toggles based on a read enable signal nRE in the memory device 20 can be generated. The controller interface 11 can receive a data signal DQ containing data DATA together with a toggling data strobe signal DQS from the memory device 20. The controller interface 11 can obtain data DATA from the data signal DQ based on the toggle timing of the data strobe signal DQS.

In a data input operation of the memory device 20, the controller interface 11 can generate a toggling data strobe signal DQS. For example, the controller interface 11 can generate a data strobe signal DQS that changes from a fixed state e.g., a high level or a low level to a toggle state before transmitting data DATA. The controller interface 11 can transmit a data signal DQ containing data DATA to the memory device 20 based on the toggle timings of the data strobe signal DQS.

The controller interface 11 can receive a ready/busy output signal nR/B from the memory device 20 via the 8th pin P28. The controller interface 11 can determine the status information of the nonvolatile memory device 20 based on the ready/busy output signal nR/B.

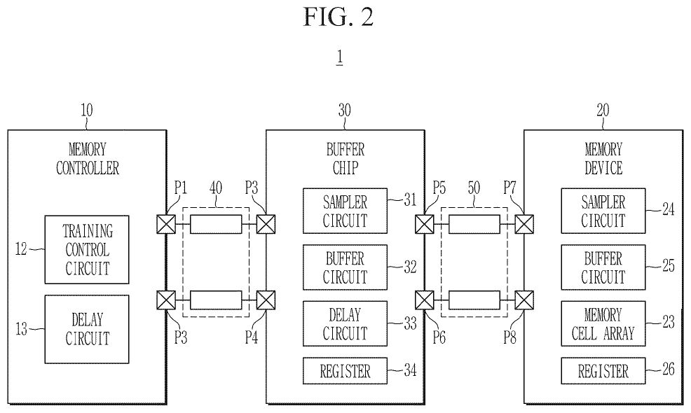

FIG. 2 is a block diagram for explaining a memory system.

Referring to FIG. 2, the memory system 1 can include a memory controller 10, a memory device 20, and a buffer chip 30. The memory controller 10 can have substantially the same configuration as the memory controller 10 illustrated in FIG. 1, and the memory device 20 can have substantially the same configuration as the memory device 20 illustrated in FIG. 1. That is, the memory system 1 illustrated in FIG. 2 can additionally have a buffer chip 30, such as an FBI Frequency Boosting Interface chip, configured between the memory controller 10 and the memory device 20.

The memory controller 10 can include a training control circuit 12 and a delay circuit 13. The memory device 20 can include a memory cell array 23, a sampler circuit 24, a buffer circuit 25, and a register 26. The buffer chip 30 can include a sampler circuit 31, a buffer circuit 32, a delay circuit 33, and a register 34.

A data signal i.e., DQ of FIG. 1 and a data strobe signal i.e., DQS of FIG. 1 can be transmitted and received between the memory controller 10 and the buffer chip 30. The data signal DQ can be transmitted and received through a transmission path 40 between the first pin P1 and the third pin P3, and the data strobe signal DQS can be transmitted and received through a transmission path 40 between the second pin P2 and the fourth pin P4.

A data signal DQ and a data strobe signal DQS can be transmitted and received between the buffer chip 30 and the memory device 20. The data signal DQ can be transmitted and received through a transmission path 50 between the fifth pin P5 and the seventh pin P7, and the data strobe signal DQS can be transmitted and received through a transmission path 50 between the sixth pin P6 and the eighth pin P8.

When the memory system 1 is powered on, the memory system 1 can perform a training operation to align the timing of the data signal DQ and the data strobe signal DQS. Specifically, based on the control signal of the training control circuit 12, the delay circuit 13 can delay the timing of the data signal DQ provided from the memory controller 10 to the buffer chip 30 to align the timing of the data signal DQ received from the buffer chip 30 and the data strobe signal DQS.

In addition, based on the control signal of the training control circuit 12, the delay circuit 33 can delay the timing of the data signal DQ or the data strobe signal DQS provided from the buffer chip 30 to the memory device 20 to align the timing of the data signal DQ and the data strobe signal DQS received from the memory device 20.

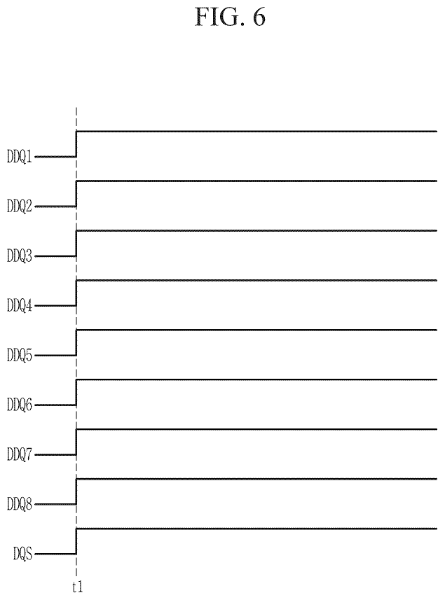

The data signal DQ and data strobe signal DQS provided from the memory controller 10 can be buffered in the buffer circuit 32. The sampler circuit 31 can sample a data signal DQ based on a data strobe signal DQS provided from the memory controller 10. Data sampled in the sampler circuit 31 can be stored in a register 34 as a code value. Based on the stored code value, the training control circuit 12 can delay the data signal DQ in the delay circuit 13. Specific details are explained in FIG. 6 and below.

The data signal DQ and data strobe signal DQS provided from the buffer chip 30 can be buffered in the buffer circuit 25. The sampler circuit 24 can sample a data signal DQ based on a data strobe signal DQS provided from a buffer chip 30. Data sampled in the sampler circuit 24 can be stored in a register 26 as a code value. Based on the stored code value, the training control circuit 12 can delay the data signal DQ or the data strobe signal DQS in the delay circuit 33. Specific details are explained in FIG. 6 and below.

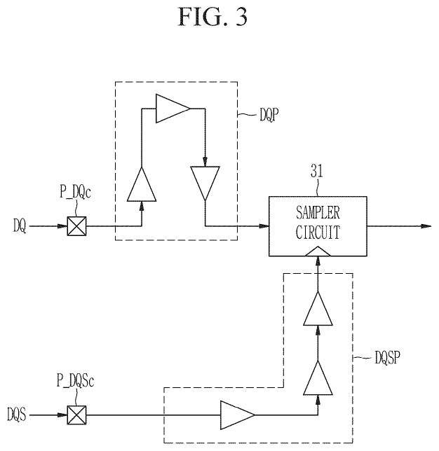

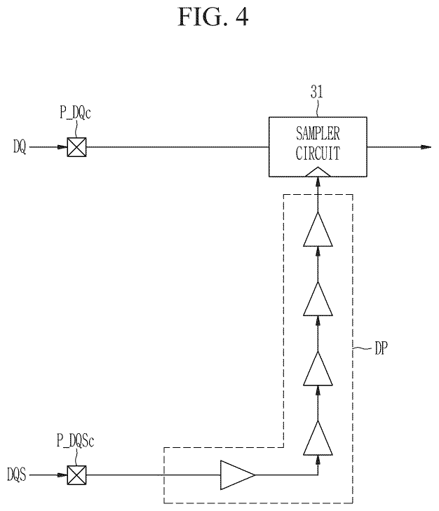

FIG. 3 and FIG. 4 are diagrams illustrating an example of tDQS2DQ. Specifically, FIG. 3 is a drawing showing an example in which the DQ path and the DQS path are implemented to be identical or similar to each other, and FIG. 4 is a drawing showing an example in which the DQS path is implemented to be longer than the DQ path.

For convenience of explanation, the DQ path is assumed to be a path from the data signal pin P_DQc to the sampler circuit 31, and the DQS path is assumed to be a path from the data strobe signal pin P_DQSc to the sampler circuit 31.

The data signal pin P_DQc can correspond to the seventh pin P27 of the controller interface 11 illustrated in FIG. 1 and the first pin P1 illustrated in FIG. 2, and the data strobe signal pin P_DQSc can correspond to the sixth pin P26 of the controller interface 11 illustrated in FIG. 1 and the second pin P2 illustrated in FIG. 2. However, this is an example, and depending on the implementation, the DQ path can be defined as various paths related to the data signal pin P_DQc and the sampler circuit 31, and the DQS path can be defined as various paths related to the data strobe signal pin P_DQSc and the sampler circuit 31.

Referring to FIG. 3, the example shown can be implemented as a matched interface type in which the length of the DQ path DQP and the length of the DQS path DQSP match each other.

In this case, since the length of the DQ path DQP and the length of the DQS path DQSP are equal to each other, the DQ delay time and the DQS delay time can also be substantially equal to each other. Here, the DQ delay time can correspond to the time taken by the DQ path DQP, and the DQS delay time can correspond to the time taken by the DQS path DQSP. Therefore, when the temperature or voltage level changes, the DQ delay time and DQS delay time can also change. Accordingly, there is no need to detect the DQS delay time separately during data training.

However, in the case of this type of matched interface, the number of branches required to implement DQ paths increases, and this can cause distortion of data signals due to impedance problems.

Referring to FIG. 4, the example shown can be implemented as an unmatched interface type, where the length of the DQS path is longer than the length of the DQ path by a delay path DP.

In this case, the data signal pad P_DQc can be placed adjacent to the sampler circuit 31. Accordingly, not only can the length of DQ paths be shorter, but the number of branches required to implement DQ paths can also be reduced. Therefore, the reliability of the data can be increased because the probability of distortion in the data signal is low.

However, in this case, since the DQ delay time and the DQS delay time do not match each other as they correspond to the delay path DP of the DQS, the DQS delay time needs to be detected separately. In particular, since the length of the DQ path is short and the DQ delay time is almost non-existent, it is essential to detect the DQS delay time. Additionally, since the DQS delay time also changes when the temperature or voltage level changes, it can be necessary to detect the DQS delay time whenever the temperature or voltage level changes.

In some examples, a timing training method of a memory system 1 can provide improved SI even in an unmatched interface type by performing a timing training operation on signals transmitted and received not only between a memory controller 10 and a buffer chip 30, but also between a buffer chip 30 and a memory device 20.

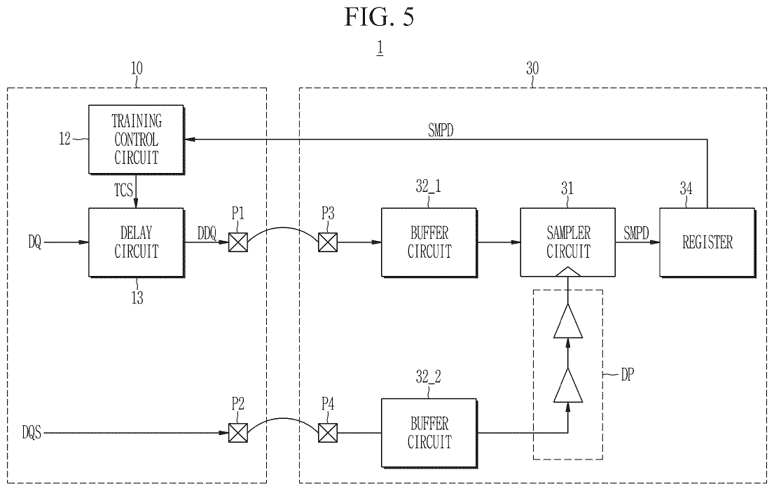

FIG. 5 is a diagram illustrating an example of an operation of a memory system. Specifically, FIG. 5 is a diagram for explaining a timing training operation between a memory controller 10 and a buffer chip 30 of a memory system 1, in an example.

Referring to FIG. 5, first, in order to perform a timing training operation between the memory controller 10 and the buffer chip 30, the buffer chip 30 can receive a chip enable signal e.g., nCE of FIG. 1 from the memory controller 10. A timing training operation can be performed between a buffer chip 30 selected by a chip enable signal and a memory controller 10.

The delay circuit 13 can delay the data signal DQ based on the timing control signal TCS received from the training control circuit 12. The delay circuit 13 can output a delayed data signal DDQ in which the data signal DQ is delayed. The delayed data signal DDQ can be transmitted to the third pin P3 of the buffer chip 30 through the first pin P1. Meanwhile, the data strobe signal DQS can be transmitted to the fourth pin P4 of the buffer chip 30 through the second pin P2.

The delayed data signal DDQ received through the third pin P3 can be buffered by the first buffer circuit 32_1, and the data strobe signal DQS received through the fourth pin P4 can be buffered by the second buffer circuit 32_2.

The sampler circuit 31 can receive a delayed data signal DDQ from the first buffer circuit 32_1 and a data strobe signal DQS from the second buffer circuit 32_2. The sampler circuit 31 can sample a delayed data signal DDQ based on a data strobe signal DQS. The sampler circuit 31 can output the sampled result as sample data SMPD, and the sample data SMPD can be stored in a register 34. Here, the sample data SMPD can include a code value containing information that the delay circuit 13 must delay the data signal DQ. The register 34 can provide sample data SMPD to the training control circuit 12, and the training control circuit 12 can control the degree to which the timing of the data signal DQ is delayed in the delay circuit 13 based on the code value included in the sample data SMPD.

As described with reference to FIGS. 3 and 4, the data strobe signal DQS can be delayed by the delay path DP compared to the data signal DQ. In order for the data signal DQ and the data strobe signal DQS to be input in an aligned state in the sampler circuit 31, the data signal DQ can need to be delayed in the delay circuit 13 as much as the data strobe signal DQS is delayed by the delay path DP. In some examples, a memory system 1 can determine a delay time value by a delay path DP through a timing training operation, and based on this, a delay circuit 13 can delay a data signal DQ.

FIGS. 6 to 8 are diagrams illustrating an example of an operation of a memory system.

Referring to FIGS. 6 to 8, in a training operation for determining a timing delay time value, the first to eighth data signals DQ1 to DQ8 can be aligned with respect to a first time point t1. That is, based on the first time point t1, the first to eighth data signals DQ1 to DQ8 can all transition from a low level to a high level. Additionally, based on the first time point t1, the data strobe signal DQS can transition from a low level to a high level. The first to eighth data signals DQ1 to DQ8 in the initial state can be provided to the delay circuit 13.

The delay circuit 13 can receive a timing control signal TCS from the training control circuit 12. During timing training operation, the delay circuit 13 can apply different delay times to the first to eighth data signals DQ1 to DQ8 based on a timing control signal TCS.

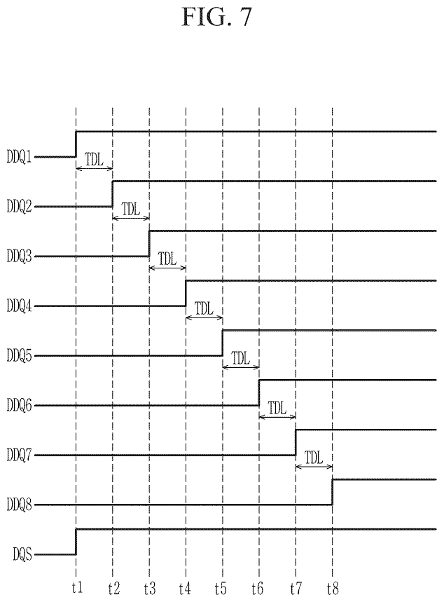

For example, as illustrated in FIG. 7, the delay circuit 13 can delay the first to eighth data signals DQ1 to DQ8 so that the delay times of the first to eighth data signals DQ1 to DQ8 sequentially increase by a unit delay time TDL. In this case, the time interval between adjacent data signals can all be the same, i.e., unit delay time TDL.

For example, the delay circuit 13 can pass the first data signal DQ1 and delay the second data signal DQ2 by one unit delay time tDLY. Accordingly, a time interval equal to the unit delay time TDL can exist between the first delayed data signal DDQ1 and the second delayed data signal DDQ2. Additionally, the delay circuit 13 can delay the third data signal DQ3 by two unit delay times i.e., 2*TDL. Accordingly, a time interval equal to the unit delay time TDL can exist between the second delayed data signal DDQ2 and the third delayed data signal DDQ3. In this manner, the delay circuit 13 can sequentially delay the fourth to eighth data signals DQ4 to DQ8.

Thereafter, the memory controller 10 can transmit the first to eighth delayed data signals DDQ1 to DDQ8 to the buffer chip 30 through the first pin P1. At this time, the memory controller 10 can transmit a data strobe signal DQS to the buffer chip 30 together with the second pin P2.

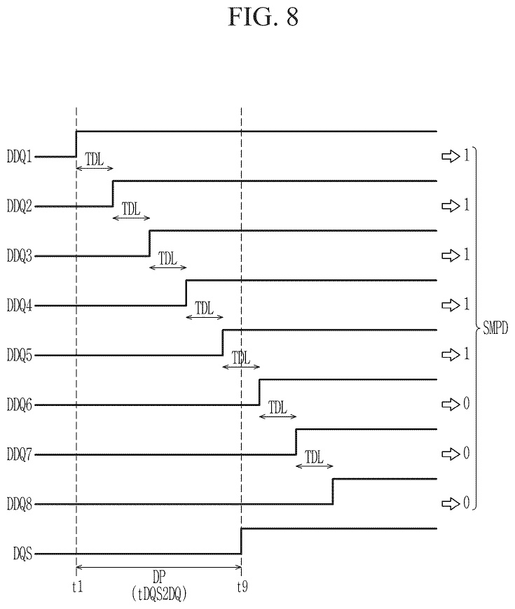

As illustrated in FIG. 8, the first to eighth delayed data signals DDQ1 to DDQ8 received by the sampler circuit 31 of the buffer chip 30 can have a time interval equal to a unit delay time TDL from each other.

The buffer chip 30 can receive a data strobe signal DQS through the fourth pad P4. The data strobe signal DQS is delayed by a delay time of tDQS2DQ by the delay path DP, and the delayed data strobe signal DQS can be provided to the sampler circuit 31.

The sampler circuit 31 can sample the first to eighth delayed data signals DDQ1 to DDQ8 based on the delayed data strobe signal DQS.

Specifically, the rising edge of the data strobe signal DQS can be delayed by a delay time caused by a delay path DP of the data strobe signal DQS. That is, the rising edge of the data strobe signal DQS can be delayed from the first time point t1 to the ninth time point t9. In this case, the sampler circuit 31 can sample the first to eighth delayed data signals DDQ1 to DDQ8 in synchronization with the rising edge of the delayed data strobe signal DQS at the ninth time point t9.

For example, at the ninth time point t9, the first to fifth delayed data signals DDQ1 to DDQ5 are at a high level, so the sampler circuit 31 can output ‘1’ as a sampling result. In addition, at the ninth time point t9, the sixth to eighth delayed data signals DDQ6 to DDQ8 are at a low level, so the sampler circuit 31 can output ‘0’ as a sampling result. As a result, the sampler circuit 1210 can output the code value of ‘11111000’ and store it in the register 34 by including it in the sample data SMPD.

Sample data SMPD containing code values can contain information about the delay time of the data strobe signal DQS. For example, as illustrated in FIG. 8, a code value of ‘11111000’ can include information that the delay time of the data strobe signal DQS is greater than four unit delay times 4*tDLY and less than five unit delay times 5*tDLY.

The memory controller 10 can transmit a read command to the buffer chip 30, and the buffer chip 30 can transmit sample data SMPD including a code value stored in a register 34 to the training control circuit 12 in response to the received read command. The training control circuit 12 can detect the delay time due to the delay path DP of the data strobe signal DQS using the code value.

However, this is only an exemplary method for convenience of explanation, and the implementations are not necessarily limited thereto. That is, depending on the implementation, the memory system 1 can additionally perform various training operations to compensate for the delay time of the data strobe signal DQS and align it with the data signal DQ.

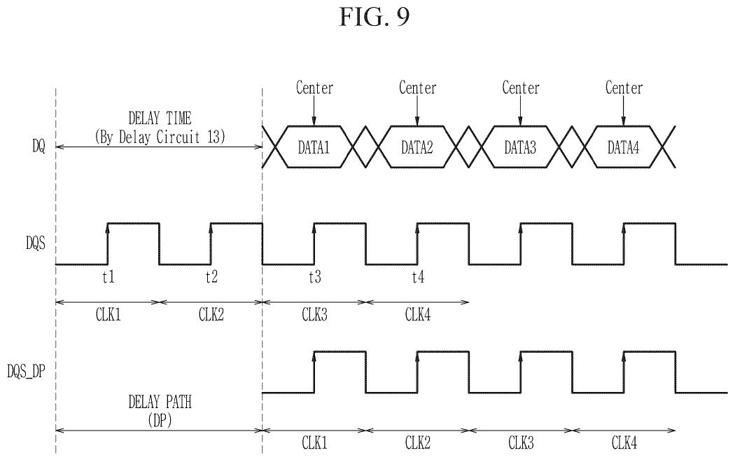

Also, for convenience of explanation, in FIGS. 6 to 8, the data signal DQ and the data strobe signal DQS are described as being aligned at the rising edge, but the memory system 1 can align the data signal DQ and the data strobe signal DQS so that the data strobe signal DQS has a rising edge at the center of the data window of the data signal DQ. Below, the above-described contents are explained with reference to FIG. 9.

FIG. 9 is a diagram illustrating an example of an operation of a memory system.

Referring to FIG. 5 and FIG. 9, a data strobe signal DQS transmitted from a second pin P2 to a fourth pin P4 can include, for example, a first clock CLK1 having a rising edge at a first time point t1, a second clock CLK2 having a rising edge at a second time point t2, a third clock CLK3 having a rising edge at a third time point t3, and a fourth clock CLK4 having a rising edge at a fourth time point t4. The first to fourth clocks CLK1 to CLK4 can be delayed by the delay time due to the delay path DP of the buffer chip 30. That is, the data strobe signal DQS input to the sampler circuit 31 can be the same signal as the data strobe signal DQS_DP delayed by the delay time due to the delay path DP.

In some examples, a memory system 1 can detect a delay time by a delay path DP of a data strobe signal DQS through the training operation described above, and can delay a data signal DQ based on the detected time. Specifically, the training control circuit 12 can cause the delay circuit 13 to delay the data signal DQ based on the detected time in correspondence to the delay time by the delay path DP of the data strobe signal DQS.

Accordingly, the data signal DQ is delayed by the first delay circuit 13, and the data strobe signal DQS is delayed by the delay path DP, so that they can be aligned in a matched state in the sampler circuit 31. Specifically, the center of the data window of the first data DATA1 included in the data signal DQ can be aligned with the rising edge of the delayed first clock CLK1, the center of the data window of the second data DATA2 can be aligned with the rising edge of the delayed second clock CLK2, the center of the data window of the third data DATA3 can be aligned with the rising edge of the delayed third clock CLK3, and the center of the data window of the fourth data DATA4 can be aligned with the rising edge of the delayed fourth clock CLK4.

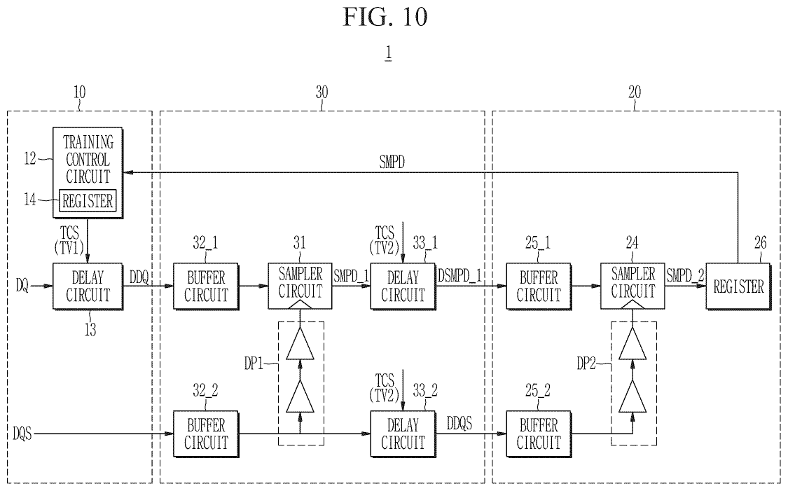

FIG. 10 is a diagram illustrating an example of an operation of a memory system. Specifically, FIG. 10 is a diagram for explaining a timing training operation between a buffer chip 30 and a memory device 20 of a memory system 1, in an example.

Referring to FIG. 10, first, in order to perform a timing training operation between the buffer chip 30 and the memory device 20, the memory device 20 can receive a chip enable signal e.g., nCE of FIG. 1 from the memory controller 10. A timing training operation can be performed between a memory device 20 selected by a chip enable signal and a memory controller 10.

The delay circuit 13 can delay the data signal DQ based on a timing control signal TCS received from the training control circuit 12, specifically, the register 14. Here, the timing control signal TCS can include a first time value TV1 for delaying the data signal DQ to correspond to the delay time by the first delay path DP1, as described with reference to FIGS. 6 to 8. That is, the delayed data signal DDQ and the data strobe signal DQS provided to the sampler circuit 31 can be in a matched state. That is, during the timing training operation of the memory system 1, in aa example, the timing training between the memory controller 10 and the buffer chip 30 can be performed prior to the timing training between the buffer chip 30 and the memory device 20.

The first delay circuit 33_1 can delay the first sample data SMPD_1 output from the sampler circuit 31 based on the timing control signal TCS received from the training control circuit 12. The timing control signal TCS input to the first delay circuit 33_1 can include a second time value TV2 for delaying the first sample data SMPD_1 by a determined time value.

In some implementations, when a timing training operation is performed between the buffer chip 30 and the memory device 20, the buffer chip 30 can operate in a bypass mode. That is, the delayed data signal DDQ delayed by the delay circuit 13 of the memory controller 10 may not be sampled by the sampler circuit 31 of the buffer chip 31 and can be input to the first delay circuit 33_1. For convenience of explanation, below, the delayed data signal DDQ input to the first delay circuit 33_1 in the bypass mode of the buffer chip 30 as described above is referred to as the first sample data SMPD_1.

The first delay circuit 33_1 can delay the first sample data SMPD_1 and output the first delayed sample data DSMPD_1. The first delayed sample data DSMPD_1 can be transmitted to the sixth pin P6 in FIG. 2 of the memory device 30 through the fifth pin P5 in FIG. 2 of the buffer chip 30.

Meanwhile, the second delay circuit 33_2 can delay the strobe signal DQS based on the timing control signal TCS received from the training control circuit 12. The timing control signal TCS input to the second delay circuit 33_2 can include a second time value TV2 for delaying the data strobe signal DQS by a determined time value. The second delay circuit 33_2 can output a delayed data strobe signal DDQS in which the data strobe signal DQS is delayed. The delayed data strobe signal DDQS can be transmitted to the eighth pin P8 in FIG. 2 of the memory device 20 through the seventh pin P7 in FIG. 2 of the buffer chip 30.

The first delayed sample data DSMPD_1 received through the seventh pin P7 can be buffered by the first buffer circuit 25_1, and the delayed data strobe signal DDQS received through the eighth pin P8 can be buffered by the second buffer circuit 25_2.

The sampler circuit 24 can receive first delayed sample data DSMPD_1 from the first buffer circuit 25_1 and can receive a delayed data strobe signal DDQS from the second buffer circuit 25_2. The sampler circuit 24 can sample the data signal DQ based on the delayed data strobe signal DDQS. The sampler circuit 24 can sample the delayed data signal DDQ based on the delayed data strobe signal DQS. The sampler circuit 24 can output the sampled result as second sample data SMPD_2, and the second sample data SMPD_2 can be stored in the register 26. Here, the second sample data SMPD_2 can include a code value including information that the first delay circuit 33_1 must delay the data signal DQ or information that the second delay circuit 33_2 must delay the data strobe DQS. The register 26 can provide the second sample data SMPD_2 to the training control circuit 12, and the training control circuit 12 can control the degree to which the timing of the data signal DQ in the first delay circuit 33_1 is delayed or the degree to which the timing of the data strobe signal DQS in the second delay circuit 33_2 is delayed based on the code value included in the second sample data SMPD_2. The method for performing timing training between the buffer chip 30 and the memory device 20 is substantially the same as the method for performing timing training between the memory controller 10 and the buffer chip 30 described with reference to FIGS. 5 to 9, and therefore, specific details are omitted below.

As described with reference to FIGS. 3 to 9, the delayed strobe signal DDQS can be delayed for a predetermined period of time by the second delay path DP2 of the memory device 20. Accordingly, the first delay circuit 33_1 or the second delay circuit 33_2 can be required to delay the first sample data SMPD_1 or the delayed data strobe signal DDQS. The first delayed sample data DSMPD_1 and the delayed data strobe signal DDQS input to the sampler circuit 24 can be provided with the first delayed sample data DSMPD_1 and the delayed data strobe signal DDQS aligned by the first delay circuit 33_1 and the second delay circuit 33_2.

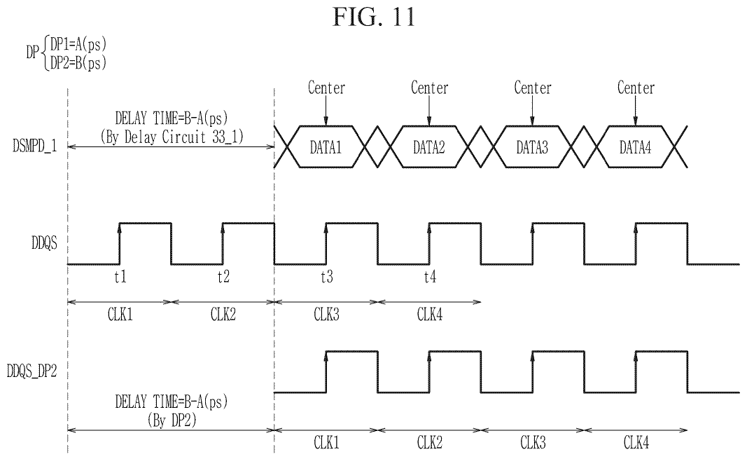

Meanwhile, the operations of the first delay circuit 33_1 and the second delay circuit 33_2 can operate differently depending on the operating characteristics of the buffer chip 30 and the memory chip 20. For example, in cases where the operation characteristic of the buffer chip 30 is fast while the operation characteristic of the memory device 20 is slow, and in cases where the operation characteristic of the buffer chip 30 is slow while the operation characteristic of the memory device 20 is fast, the operations of the first delay circuit 33_1 and the second delay circuit 33_2 can be different from each other. Specific details related to this are explained in FIG. 11 and below.

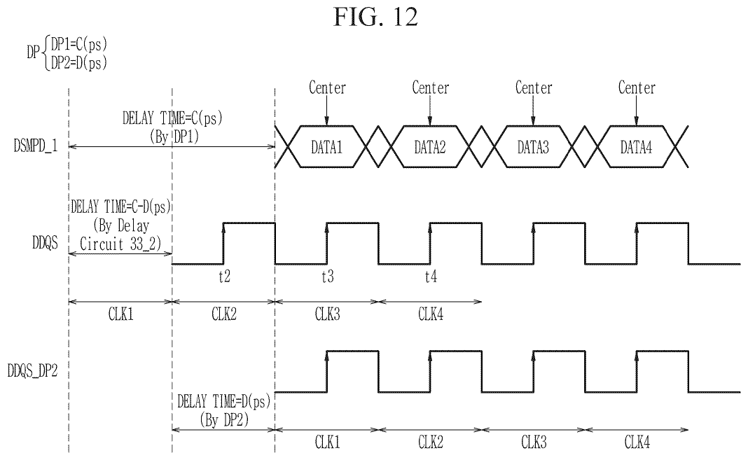

FIG. 11 and FIG. 12 are diagrams illustrating an example of an operation of a memory system.

Referring to FIGS. 10 and 11, for convenience of explanation, it is assumed that the delay time along the first delay path DP1 in the buffer chip 30 is A ps e.g., 100 ps, the delay time along the second delay path DP2 in the memory device 20 is B ps e.g., 1100 ps, and the value of A is smaller than the value of B. That is, the implementation illustrated in FIG. 11 can correspond to a case where the operating characteristics of the buffer chip 30 are fast, while the operating characteristics of the memory chip 20 are slow.

As described with reference to FIGS. 2 to 9, based on the control of the training control circuit 12, the delay circuit 13 of the memory controller 10 can delay the data signal DQ to correspond to the delay time along the first delay path DP1. That is, the timing training operation between the memory controller 10 and the buffer chip 30 is completed, so that the delayed data signal DDQ or the first sample data SMPD_1 and the data strobe signal DQS can be aligned with each other.

The memory system 1 can subsequently perform a timing training operation between the buffer chip 30 and the memory device 20. At this time, the buffer chip 30 operates in a bypass mode so that the delayed data signal DDQ or first sample data SMPD_1, referred to as first sample data SMPD_1 hereinafter for convenience of explanation received from the buffer circuit 32_1 can be input to the first delay circuit 33_1.

The first sample data SMPD_1 input to the first delay circuit 33_1 can be delayed by a delay time corresponding to the first delay path DP1, i.e., A ps, by the delay circuit 13 of the memory controller 10. Meanwhile, the data strobe signal DQS input to the second delay circuit 33_2 is input to the second delay circuit 33_2 without passing through the first delay path DP1, and thus can be ahead of the first sample data SMPD_1 by A ps.

Meanwhile, the data strobe signal DQS input to the sampler circuit 24 of the memory device 20 can have a delay time due to the second delay path DP2 of the memory device 20, that is, a delay time of B ps. Accordingly, in order to align the first delayed sample data DSMPD_1 input to the sampler circuit 24 of the memory device 20 and the delayed data strobe signal DDQS, the first delay circuit 33_1 can delay the first sample data SMPD_1 by B-A ps, which is the difference between the first delay time A ps by the first delay path DP1 and the second delay time B ps by the second delay path DP2.

As illustrated in FIG. 11, the first delayed sample data DSMPD_1 can be delayed by B-A ps by the first delay circuit 33_1 of the buffer chip 30. The data strobe signal DQS is not delayed by the second delay circuit 33_2, but can be delayed by B ps by the second delay path DP2 of the memory device 20. Accordingly, the first delayed sample data DSMPD_1 delayed by the first delay circuit 33_1 input to the sampler circuit 24 of the memory device 20 and the delayed data strobe signal DDQS_DP2 delayed by the second delay path DP2 can be aligned.

That is, the center of the data window of the first data DATA1 included in the first delayed sample data DSMPD_1 can be aligned with the rising edge of the first clock CLK1 of the delayed data strobe signal DDQS_DP2 delayed by the second delay path DP2, the center of the data window of the second data DATA2 can be aligned with the rising edge of the second clock CLK2 of the delayed data strobe signal DDQS_DP2 delayed by the second delay path DP2, the center of the data window of the third data DATA3 can be aligned with the rising edge of the third clock CLK3 of the delayed data strobe signal DDQS_DP2 delayed by the second delay path DP2, and the center of the data window of the fourth data DATA4 can be aligned with the rising edge of the fourth clock CLK3 of the delayed data strobe signal DDQS_DP2 delayed by the second delay path DP2. It can be aligned with the rising edge of the clock CLK4.

Referring to FIGS. 10 and 12, for convenience of explanation, unlike the implementation in FIG. 11, it is assumed that the delay time along the first delay path DP1 in the buffer chip 30 is C ps e.g., 1100 ps, the delay time along the second delay path DP2 in the memory device 20 is D ps e.g., 100 ps, and the value of C is greater than the value of D. That is, the implementation illustrated in FIG. 11 can correspond to a case where the operating characteristic of the buffer chip 30 is slow, while the operating characteristic of the memory chip 20 is fast.

The first sample data SMPD_1 input to the first delay circuit 33_1 can be delayed by a delay time corresponding to the first delay path DP1, i.e., C ps, by the delay circuit 13 of the memory controller 10. Meanwhile, the data strobe signal DQS input to the second delay circuit 33_2 is input to the second delay circuit 33_2 without passing through the first delay path DP1, and thus can be ahead of the first sample data SMPD_1 by C ps.

Meanwhile, the data strobe signal DQS input to the sampler circuit 24 of the memory device 20 can have a delay time due to the second delay path DP2 of the memory device 20, i.e., a delay time of D ps. Accordingly, in order to align the first delayed sample data DSMPD_1 input to the sampler circuit 24 of the memory device 20 and the delayed data strobe signal DDQS, the second delay circuit 33_2 can delay the data strobe signal DQS by C-D ps, which is the difference between the first delay time C ps by the first delay path DP1 and the second delay time D ps by the second delay path DP2.

As illustrated in FIG. 12, the first delayed sample data DSMPD_1 can be delayed by C ps by the first delay path DP1 of the buffer chip 30. The data strobe signal DQS can be delayed by C-D ps by the second delay circuit 33_2 and by D ps by the second delay path DP2 of the memory device 20. Accordingly, the first delayed sample data DSMPD_1 input to the sampler circuit 24 of the memory device 20 and the delayed data strobe signal DDQS_DP2 delayed by the second delay circuit 33_2 and the second delay path DP2 can be aligned.

That is, the center of the data window of the first data DATA1 included in the first delayed sample data DSMPD_1 can be aligned with the rising edge of the first clock CLK1 of the delayed data strobe signal DDQS_DP2 delayed by the second delay path DP2, the center of the data window of the second data DATA2 can be aligned with the rising edge of the second clock CLK2 of the delayed data strobe signal DDQS_DP2 delayed by the second delay path DP2, the center of the data window of the third data DATA3 can be aligned with the rising edge of the third clock CLK3 of the delayed data strobe signal DDQS_DP2 delayed by the second delay path DP2, and the center of the data window of the fourth data DATA4 can be aligned with the rising edge of the fourth clock CLK3 of the delayed data strobe signal DDQS_DP2 delayed by the second delay path DP2. It can be aligned with the rising edge of the clock CLK4.

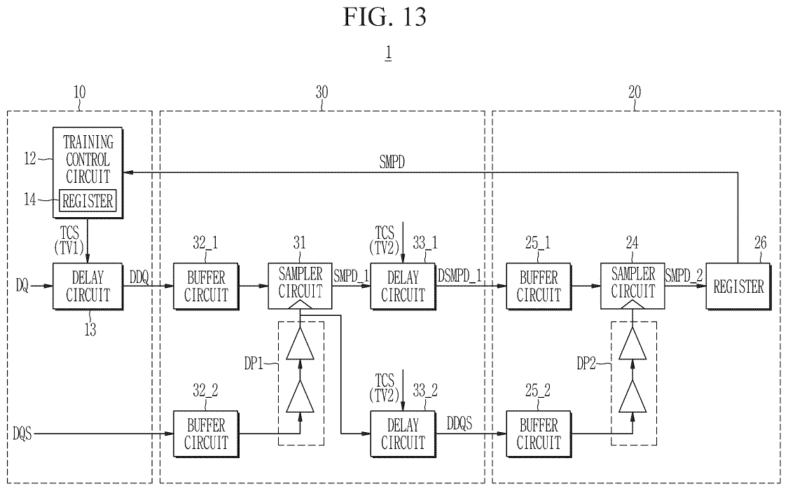

FIG. 13 is a diagram illustrating an example of an operation of a memory system. Below, differences from the memory system according to some implementations illustrated in FIG. 10 will be mainly described.

Referring to FIG. 13, unlike FIG. 12, the data strobe signal DQS input to the second delay circuit 33_2 can be input after being transmitted through the first delay path DP1 of the buffer chip 30. That is, the first sample data SMPD_1 input to the first delay circuit 33_1 and the data strobe signal DQS input to the second delay circuit 33_2 can be aligned.

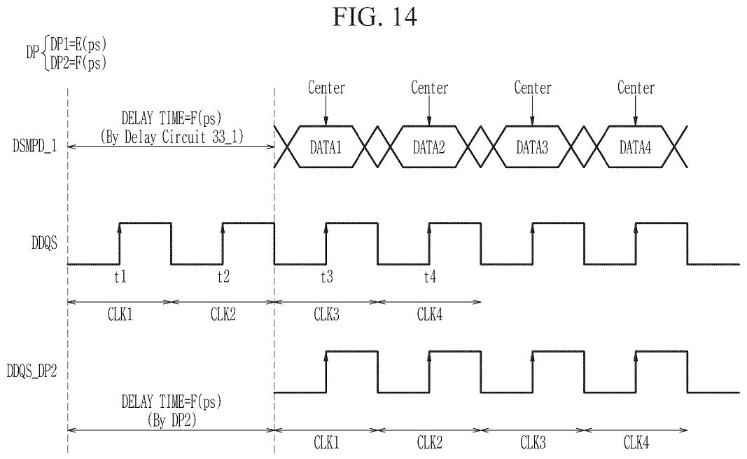

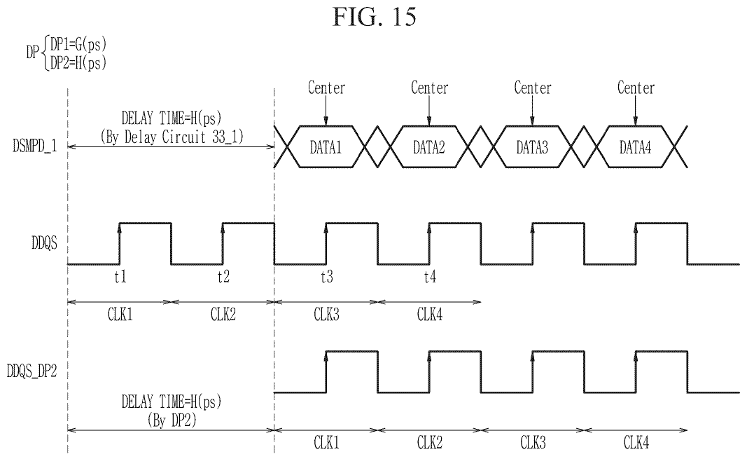

FIGS. 14 and 15 are diagrams illustrating an example of an operation of a memory system.

Referring to FIGS. 13 and 14, for convenience of explanation, it is assumed that the delay time along the first delay path DP1 in the buffer chip 30 is E ps e.g., 100 ps, the delay time along the second delay path DP2 in the memory device 20 is F ps e.g., 1100 ps, and the value of E is smaller than the value of F. That is, the implementation illustrated in FIG. 14 can correspond to a case where the operating characteristic of the buffer chip 30 is fast, while the operating characteristic of the memory chip 20 is slow.

The delayed data strobe signal DDQS input to the sampler circuit 24 of the memory device 20 can be delayed by the delay time due to the second delay path DP2, i.e., F ps. Accordingly, in order to align the first delayed sample data DSMPD_1 input to the sampler circuit 24 of the memory device 20 and the delayed data strobe signal DDQS, the first delay circuit 33_1 can delay the first sample data SMPD_1 by the second delay time, F ps, by the second delay path DP2.

Accordingly, the center of the data window of the first data DATA1 included in the first delayed sample data DSMPD_1 can be aligned with the rising edge of the first clock CLK1 of the delayed data strobe signal DDQS_DP2 delayed by the second delay path DP2, the center of the data window of the second data DATA2 can be aligned with the rising edge of the second clock CLK2 of the delayed data strobe signal DDQS_DP2 delayed by the second delay path DP2, the center of the data window of the third data DATA3 can be aligned with the rising edge of the third clock CLK3 of the delayed data strobe signal DDQS_DP2 delayed by the second delay path DP2, and the center of the data window of the fourth data DATA4 can be aligned with the rising edge of the fourth clock CLK3 of the delayed data strobe signal DDQS_DP2 delayed by the second delay path DP2. It can be aligned with the rising edge of the clock CLK4.

Referring to FIGS. 13 and 15, for convenience of explanation, it is assumed that the delay time along the first delay path DP1 in the buffer chip 30 is G ps e.g., 1100 ps, the delay time along the second delay path DP2 in the memory device 20 is H ps e.g., 100 ps, and the value of G is greater than the value of H. That is, the implementation illustrated in FIG. 15 can correspond to a case where the operating characteristic of the buffer chip 30 is slow, while the operating characteristic of the memory chip 20 is fast.

The delayed data strobe signal DDQS input to the sampler circuit 24 of the memory device 20 can be delayed by the delay time due to the second delay path DP2, i.e., H ps. Accordingly, in order to align the first delayed sample data DSMPD_1 input to the sampler circuit 24 of the memory device 20 and the delayed data strobe signal DDQS, the first delay circuit 33_1 can delay the first sample data SMPD_1 by the second delay time, H ps, by the second delay path DP2.

Accordingly, the center of the data window of the first data DATA1 included in the first delayed sample data DSMPD_1 can be aligned with the rising edge of the first clock CLK1 of the delayed data strobe signal DDQS_DP2 delayed by the second delay path DP2, the center of the data window of the second data DATA2 can be aligned with the rising edge of the second clock CLK2 of the delayed data strobe signal DDQS_DP2 delayed by the second delay path DP2, the center of the data window of the third data DATA3 can be aligned with the rising edge of the third clock CLK3 of the delayed data strobe signal DDQS_DP2 delayed by the second delay path DP2, and the center of the data window of the fourth data DATA4 can be aligned with the rising edge of the fourth clock CLK3 of the delayed data strobe signal DDQS_DP2 delayed by the second delay path DP2. It can be aligned with the rising edge of the clock CLK4.

As described above, in some examples, the memory system 1 can provide improved SI by performing timing training operations between the buffer chip and the memory device as well as timing training operations between the memory controller and the buffer chip.

Meanwhile, a method for performing timing training between a data signal DQ and a data strobe signal DQS has been described with reference to FIGS. 1 to 15, but the implementation is not limited thereto, and the memory system 1 can also perform timing training between a command and a command clock.

The memory system 1 can perform the above-described timing training operation for, for example, a command transmitted through a transmission line of a data signal DQ for example, between P27 and P17 in FIG. 1 and a command clock signal transmitted through a transmission line of a data strobe signal DQS for example, between P26 and P16 in FIG. 1.

Alternatively, when the controller interface 11 in FIG. 1 and the memory interface 21 in FIG. 1 and the interface of the buffer chip are implemented as a Separate Command Address SCA interface, the command and command clock signals can be transmitted through a transmission line that is separated from the transmission lines of the data signal DQ and the data strobe signal DQS. The above-described timing training operation can be performed for command and command clock signals transmitted through separate transmission lines.

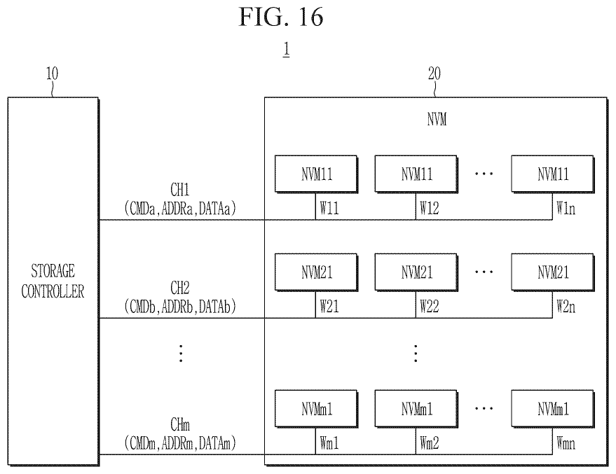

FIG. 16 is a diagram illustrating an example of an operation of a memory system.

Referring to FIG. 16, the memory system 1 can include a memory controller 10 and a memory device 20.

The memory system 1 can support multiple channels CH1 to CHm, and the memory controller 10 and the memory device 20 can be connected through multiple channels CH1 to CHm. For example, the memory system 1 can be implemented as a storage device such as an SSD Solid State Drive.

The memory device 20 can include a plurality of nonvolatile memory devices NVM11 to NVMmn. Each of the nonvolatile memory devices NVM11 to NVMmn can be connected to one of a plurality of channels CH1 to CHm through a corresponding way. For example, nonvolatile memory devices NVM11 to NVM1n can be connected to a first channel CH1 through ways W11 to W1n, and nonvolatile memory devices NVM21 to NVM2n can be connected to a second channel CH2 through ways W21 to W2n.

In some implementations, each of the nonvolatile memory devices NVM11 to NVMmn can be implemented as an arbitrary memory unit that can operate according to individual commands from the memory controller 10. For example, each of the nonvolatile memory devices NVM11 to NVMmn can be implemented as a chip or a die, but the implementation is not limited thereto.

The memory controller 10 can transmit and receive signals with the memory device 20 through multiple channels CH1 to CHm. For example, the memory controller 10 can transmit commands CMDa to CMDm, addresses ADDRa to ADDRm, and data DATAa to DATAm to the memory device 20 through channels CH1 to CHm, or receive data DATAa to DATAm from the memory device 20.

The memory controller 10 can select one of the nonvolatile memory devices NVM11 to NVMmn connected to each channel through each channel and transmit and receive signals with the selected nonvolatile memory device.

For example, the memory controller 10 can select a nonvolatile memory device NVM11 among the nonvolatile memory devices NVM11 to NVM1n connected to the first channel CH1. The memory controller 10 can transmit a command CMDa, an address ADDRa, and data DATAa to a selected nonvolatile memory device NVM11 through a first channel CH1, or receive data DATAa from the selected nonvolatile memory device NVM11.

The memory controller 10 can transmit and receive signals in parallel with the memory device 20 through different channels. For example, the memory controller 10 can transmit a command CMDb to the memory device 20 through a second channel CH2 while transmitting a command CMDa to the memory device 20 through a first channel CH1. For example, the memory controller 10 can receive data DATAb from the memory device 20 through the second channel CH2 while receiving data DATAa from the memory device 20 through the first channel CH1.

The memory controller 10 can control the overall operation of the memory device 20. The memory controller 10 can control each of the nonvolatile memory devices NVM11 to NVMmn connected to the channels CH1 to CHm by transmitting signals to the channels CH1 to CHm. For example, the memory controller 10 can control a selected one of the nonvolatile memory devices NVM11 to NVM1n by transmitting a command CMDa and an address ADDRa to the first channel CH1.

Each of the nonvolatile memory devices NVM11 to NVMmn can operate under the control of the memory controller 10. For example, a nonvolatile memory device NVM11 can program data DATAa according to a command CMDa and an address ADDRa provided to the first channel CH1. For example, a nonvolatile memory device NVM21 can read data DATAb according to a command CMDb and an address ADDRb provided to a second channel CH2 and transmit the read data DATAb to a memory controller 10.

Meanwhile, in FIG. 16, a memory device 20 is illustrated as communicating with a memory controller 10 through m channels, and the memory device 20 includes n nonvolatile memory devices corresponding to each channel, but the implementation is not necessarily limited thereto, and the number of channels and the number of nonvolatile memory devices connected to one channel can be variously changed.

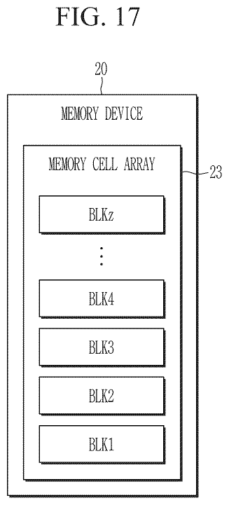

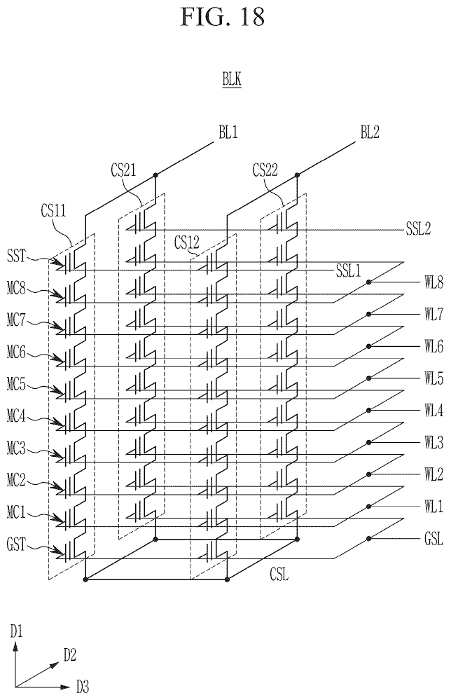

FIG. 17 is a diagram illustrating an example of a memory device. FIG. 18 is a circuit diagram illustrating an example of one memory block among a plurality of memory blocks included in a memory cell array.

Referring to FIG. 17, a memory device 20 includes a memory cell array 23, and the memory cell array 23 can include a plurality of memory blocks BLK1 to BLKz.

Referring to FIG. 18, a memory block BLK can include multiple cell strings CS11-CS12, CS21-CS22. Multiple cell strings CS11-CS12, CS21-CS22 can be connected between bit lines BL1, BL2 and a common source line CSL. Each of the multiple cell strings CS11-CS12, CS21-CS22 can include a string select transistor SST, multiple memory cells MC1-MC8, and a ground select transistor GST.

The string select transistors SST can be connected to the string select lines SSL1-SSL3, respectively. Each of the multiple memory cells MC1-MC8 can be connected to multiple WL1-WL8. A ground select transistor GST can be connected to a ground select line GSL. A string select transistor SST can be connected to bit lines BL1, BL2, and a ground select transistor GST can be connected to a common source line CSL. Wordlines of the same height e.g., WL1 can be connected in common. For example, when programming memory cells connected to the first word line WL1 and included in the cell string CS11, CS12, the first word line WL1 and the first string select line SSL1 can be selected.

In some implementations, the program operation or read operation can be performed on a row-by-row basis of cell strings CS11-CS22. Cell strings CS11-CS22 can be selected in one row by string selection lines SSL1-SSL2.

In a selected row of cell strings CS11-CS22, program operations or read operations can be performed on a page-by-page basis. A page can be a single row of memory cells connected to a single wordline. In a selected row of cell strings CS11-CS22, memory cells can be selected in units of pages by word lines WL1-WL8.

In some implementations, a plurality of cell strings CS11-CS12, CS21-CS22 can be formed in a direction perpendicular to a substrate not shown, and a string select transistor SST, a plurality of memory cells MC1-MC8, and a ground select transistor GST can be stacked in a direction perpendicular to the substrate not shown.

That is, the memory block BLK will be a memory block with a three-dimensional structure. Memory cells included in a memory block having a three-dimensional structure can be charge trap flash CTF memory cells. Charge capture flash memory cells can store data by trapping charges in a charge storage film.

Meanwhile, the memory block BLK illustrated in FIG. 18 is exemplary and the implementation is not necessarily limited thereto. For example, compared to the memory block BLK illustrated in FIG. 18, the number of rows of cell strings can be increased or decreased, and as the number of rows of cell strings is changed, the number of string select lines or ground select lines connected to the rows of cell strings, and the number of cell strings connected to one bit line can also be changed.

Also, compared to the memory block BLK illustrated in FIG. 18, the number of columns of cell strings can be increased or decreased, and as the number of columns of cell strings is changed, the number of bit lines connected to the columns of cell strings and the number of cell strings connected to one string selection line can also be changed.

Additionally, compared to the memory block BLK illustrated in FIG. 18, the height of the cell strings can be increased or decreased, and the number of memory cells stacked in each of the cell strings can be increased or decreased. As the number of memory cells stacked in each cell string changes, the number of word lines can also change.

Additionally, the number of string select transistors or ground select transistors provided for each of the cell strings can be increased. As the number of string select transistors or ground select transistors provided for each of the cell strings changes, the number of string select lines or ground select lines can also change. As the number of string select transistors or ground select transistors increases, the string select transistors or ground select transistors can be stacked in the same form as the memory cells MC1-MC8.

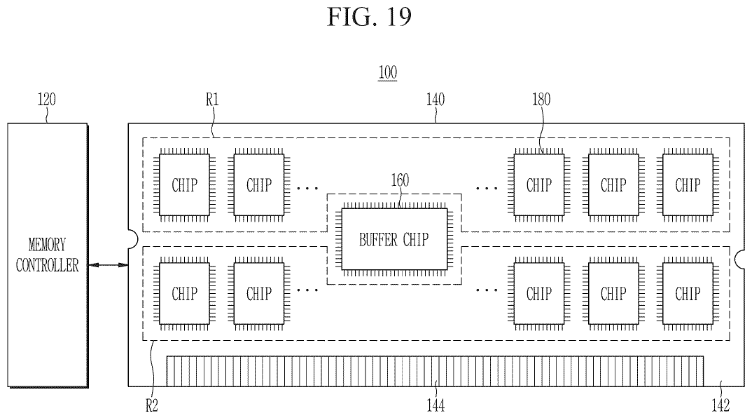

FIG. 19 is a diagram illustrating an example of a memory system.

Referring to FIG. 19, the memory system 100 includes a memory controller 120 and a memory module 140, and the memory module 140 can include one or more memory chips 180 each including a memory cell array, and a buffer chip 160 for routing transmission and reception signals between the memory chips 180 and the memory controller 120 or managing memory operations for the memory chips 180.

The memory chips 180 of the memory module 140 can be divided into a first rank R1 and a second rank R2. The timing training operation described with reference to FIGS. 1 to 15 can be performed between the memory controller 120 and the buffer chip 160, and between the buffer chip 160 and the memory chips 180. The specific details are the same as described above, so they are omitted below.

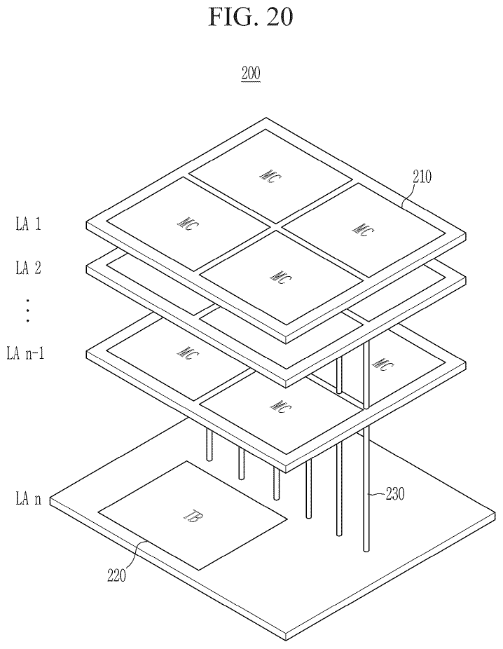

FIG. 20 is a diagram illustrating an example of a memory system.

Referring to FIG. 20, a semiconductor package 200 can include a plurality of layers LA1 to LAn. Each of the first layer LA1 to the n-1th layer LAn can be a memory layer or memory chip; 210 including a plurality of memory cores MC. A memory core MC can include a memory cell array for storing data, a row decoder, a column decoder, and a sense amplifier. The nth layer LAn can be a buffer layer or buffer chip. In a semiconductor package 200, layers LA1 to LAn of a laminated structure can be interconnected through through silicon vias TSVs, 230.

The buffer layer LAn communicates with an external memory controller and memory layers LA1 to LAn-1, and can route transmission and reception signals between the memory layers LA1 to LAn-1 and the memory controller. Furthermore, the buffer layer LAn can queue signals received from the memory controller or memory layers LA1 to LAn-1.

Additionally, the buffer layer LAn can include a training block 220. The buffer layer LAn can perform training operations on the memory layers LA1 to LAn-1 using the training block 220. Specifically, the training block 220 can perform timing training operations for memory layers LA1 to LAn-1 based on the control of an external memory controller. In some implementations, the buffer layer LAn can perform a training operation for the memory layers LA1 to LAn-1 and generate timing compensation information for transmission and reception signals between the memory layers LA1 to LAn-1 for each memory core MC. The training operation method can be applied to the implementations described in FIGS. 1 to 15.

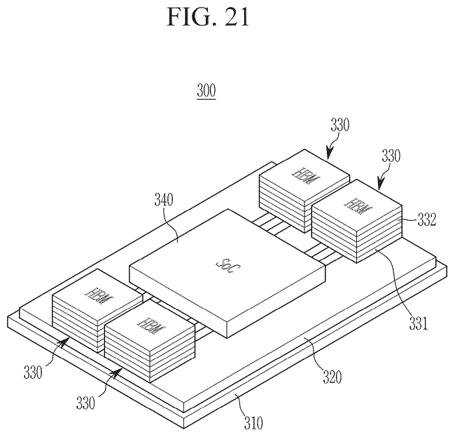

FIG. 21 is a diagram illustrating an example of a memory system.

A semiconductor package 300 can be a memory module including at least one stack semiconductor chip 330 and a system-on-chip SOC 340 mounted on a package substrate 310, such as a printed circuit board. An interposer 320 can optionally be further provided on the package substrate 310. The stack semiconductor chip 330 can be formed as a chip-on-chip CoC. A stack semiconductor chip 330 can include at least one memory chip 332 stacked on a buffer chip 331, such as a logic chip. The buffer chip 331 and at least one memory chip 332 can be connected to each other by a through silicon via TSV. The buffer chip 331 can perform a training operation for the memory chip 332, and the training operation method of the buffer chip 331 can be applied to the implementations described in FIGS. 1 to 15. The stack semiconductor chip 330 can be, for example, a high bandwidth memory HBM of 500 GB/sec to 1 TB/sec or more.

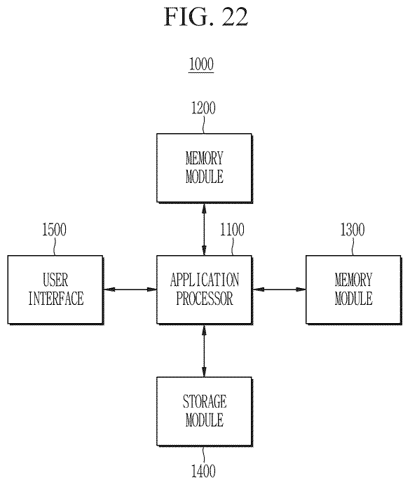

FIG. 22 is a diagram illustrating an example of a mobile system to which an example of a memory system is applied.

Referring to FIG. 22, the mobile system 1000 can include an application processor 1100, a network module 1200, a memory module 1300, a storage module 1400, and a user interface 1500.

The network module 1200 can communicate with external devices. For example, the network module 1200 can support wireless communications such as CDMA Code Division Multiple Access, GSM Global System for Mobile communication, WCDMA wideband CDMA, CDMA-2000, TDMA Time Division Multiple Access, LTE Long Term Evolution, Wimax, WLAN, UWB, Bluetooth, WI-DI, etc.

The memory module 1300 can operate as a main memory, operating memory, buffer memory, or cache memory of the mobile system 1000. The memory module 1300 can include volatile random access memory such as DRAM, SDRAM, DDR SDRAM, DDR2 SDRAM, DDR3 SDRAM, LPDDR SDARM, LPDDR3, SDRAM, LPDDR3 SDRAM, etc., or nonvolatile random access memory such as PRAM, ReRAM, MRAM, FRAM, etc.

The storage module 1400 can store data. For example, the storage module 1400 can store data received from outside. The storage module 1400 can transmit data stored in the storage module 1400 to the application processor 1100. For example, the storage module 1400 can be implemented with a nonvolatile semiconductor memory device such as PRAM, MRAM, RRAM, NAND flash, NOR flash, or a three-dimensional structured NAND flash. For example, the storage module 1400 can be provided as a solid state drive SSD, a multimedia card MMC, an embedded multimedia card eMMC, a universal flash storage UFS, etc.

In some implementations, the storage module 1400 can include a memory controller, a buffer chip, and a memory device, as described in FIGS. 1 through 15. The storage module 1400 can perform timing training operations between the memory controller and the buffer chip, and between the buffer chip and the memory device, based on the control of the memory controller. Through timing training operations, the storage module 1400 can provide improved SI. Specific details regarding the training movements are the same as those described with reference to FIGS. 1 to 15, and are therefore omitted below.

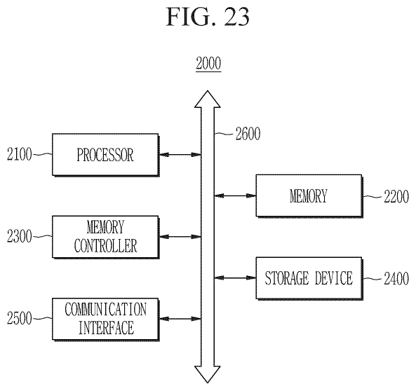

FIG. 23 is a diagram illustrating an example of a computing device to which an example of a memory system is applied.

Referring to FIG. 23, a computing device 2000 can include a processor 2100, a memory 2200, a memory controller 2300, a storage device 2400, a communication interface 2500, and a bus 2600. The computing device 2000 can further include other general-purpose components.

The processor 2100 can control the overall operation of each component of the computing device 2000. The processor 2100 can be implemented as at least one of various processing units such as a CPU, an AP, and a GPU.

Memory 2200 can store various data and commands. The memory controller 2300 can control the transfer of data or commands to and from the memory 2200. In some implementations, the memory controller 2300 can be provided as a separate chip from the processor 2100. In some implementations, the memory controller 2300 can be provided as an internal component of the processor 2100.

The storage device 2400 non-temporarily stores programs and data. In some implementations, the storage device 2400 can include a memory controller, a buffer chip, and a memory device, as described in FIGS. 1 through 15. The storage device 2400 can perform timing training operations between the memory controller and the buffer chip, and between the buffer chip and the memory device, based on the control of the memory controller. Through timing training operations, the storage device 2400 can provide improved SI. Specific details regarding the training movements are the same as those described with reference to FIGS. 1 to 15, and are therefore omitted below.

The communication interface 2500 can support wired and wireless Internet communication of the computing device 2000. The communication interface 2500 can support various communication methods other than Internet communication.

The bus 2600 can provide communication capabilities between components of the computing device 2000. The bus 2600 can include at least one type of bus depending on the communication protocol between the components.

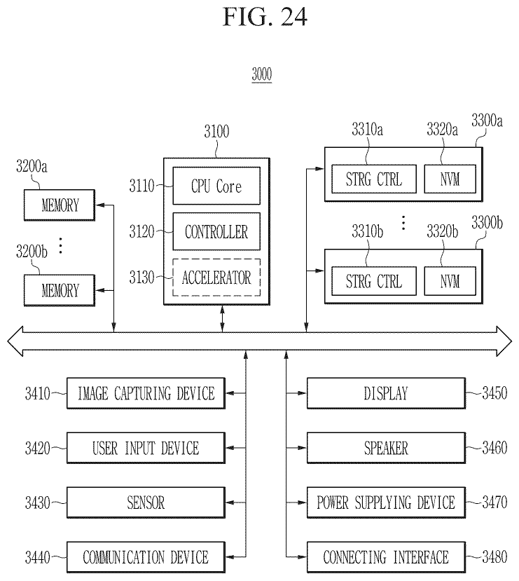

FIG. 24 is a diagram illustrating an example of a system to which an example of a memory system is applied.

Referring to FIG. 24, the system 3000 can be a mobile system, such as a mobile phone, a smart phone, a tablet personal computer, a wearable device, a healthcare device, or an Internet of Things IoT device. However, the implementation is not necessarily limited thereto, and the system 3000 of FIG. 19 can be a personal computer, a laptop computer, a server, a media player, or an automotive device such as a navigation device.

The system 3000 can include a main processor 3100, a memory 3200a, 3200b, and a storage device 3300a, 3300b, and can additionally include one or more of a shooting device 3410, a user input device 3420, a sensor 3430, a communication device 3440, a display 3450, a speaker 3460, a power supply device 3470, and a connecting interface 3480.

The main processor 3100 can control the overall operation of the system 3000, more specifically, the operation of other components that make up the system 3000. Such a main processor 3100 can be implemented as a general-purpose processor, a dedicated processor, or an application processor.

The main processor 3100 can include one or more CPU cores 3110 and can further include a controller 3120 for controlling memory 3200a, 3200b and/or storage devices 3300a, 3300b. In some implementations, the main processor 3100 can further include an accelerator 3130, which is a dedicated circuit for high-speed data operations such as AI Artificial Intelligence data operations. Such an accelerator 3130 can include a GPU Graphics Processing Unit, an NPU Neural Processing Unit, and/or a DPU Data Processing Unit, and can be implemented as a separate chip that is physically independent from other components of the main processor 3100.

Memory 3200a, 3200b can be used as a main memory device of the system 3000 and can include volatile memory such as SRAM and/or DRAM, but can also include non-volatile memory such as flash memory, PRAM and/or RRAM. The memory 3200a, 3200b can also be implemented within the same package as the main processor 3100.

The storage device 3300a, 3300b can function as a non-volatile storage device that stores data regardless of whether power is supplied, and can have a relatively large storage capacity compared to the memory 3200a, 3200b. A storage device 3300a, 3300b can include a storage controller 3310a, 3310b and a nonvolatile memory 3320a, 3320b that stores data under the control of the storage controller 3310a, 3310b. The nonvolatile memory 3320a, 3320b can include flash memory of a 2D 2-dimensional structure or a 3D 3-dimensional V-NAND Vertical NAND structure, but can also include other types of nonvolatile memory such as PRAM and/or RRAM.

The storage device 3300a, 3300b can be included in the system 3000 physically separated from the main processor 3100, or can be implemented within the same package as the main processor 3100. In addition, the storage device 3300a, 3300b can have a form such as a solid state device SSD or a memory card, and can be detachably connected to other components of the system 3000 through an interface such as a connection interface 3480 to be described later. Such storage devices 3300a, 3300b can be devices to which standard specifications such as UFS Universal Flash Storage, eMMC embedded multi-media card or NVMe non-volatile memory express are applied, but are not necessarily limited thereto.

In some implementations, the storage device 3300a, 3300b can include a memory controller, a buffer chip, and a memory device, as described in FIGS. 1 through 15. The storage device 3300a, 3300b can perform timing training operations between the memory controller and the buffer chip, and between the buffer chip and the memory device, based on the control of the memory controller. Through timing training operations, the storage device 3300a, 3300b can provide improved SI. Specific details regarding the training movements are the same as those described with reference to FIGS. 1 to 15, and are therefore omitted below.

The photographing device 3410 can capture still or moving images and can be a camera, a camcorder, and/or a webcam.

The user input device 3420 can receive various types of data input from a user of the system 3000, and can be a touch pad, a keypad, a keyboard, a mouse, and/or a microphone.

The sensor 3430 can detect various types of physical quantities that can be obtained from outside the system 3000 and convert the detected physical quantities into electrical signals. Such sensors 1430 can be temperature sensors, pressure sensors, light sensors, position sensors, acceleration sensors, biosensors, and/or gyroscope sensors.

The communication device 3440 can transmit and receive signals between other devices outside the system 3000 according to various communication protocols. Such a communication device 3440 can be implemented including an antenna, a transceiver, and/or a modem.

The display 3450 and speaker 3460 can function as output devices that output visual information and auditory information, respectively, to the user of the system 3000.

The power supply unit 3470 can appropriately convert power supplied from a battery not shown built into the system 3000 and/or an external power source and supply it to each component of the system 3000.

A connection interface 3480 can provide a connection between the system 3000 and an external device that is connected to the system 3000 and can exchange data with the system 3000. The connection interface 3480 can be implemented in various interface methods such as ATA Advanced Technology Attachment, SATA Serial ATA, e-SATA external SATA, SCSI Small Computer Small Interface, SAS Serial Attached SCSI, PCI Peripheral Component Interconnection, PCIe PCI express, NVMe, IEEE 1394, USB universal serial bus, SD secure digital card, MMC multi-media card, eMMC, UFS, eUFS embedded Universal Flash Storage, CF compact flash card interface, etc.

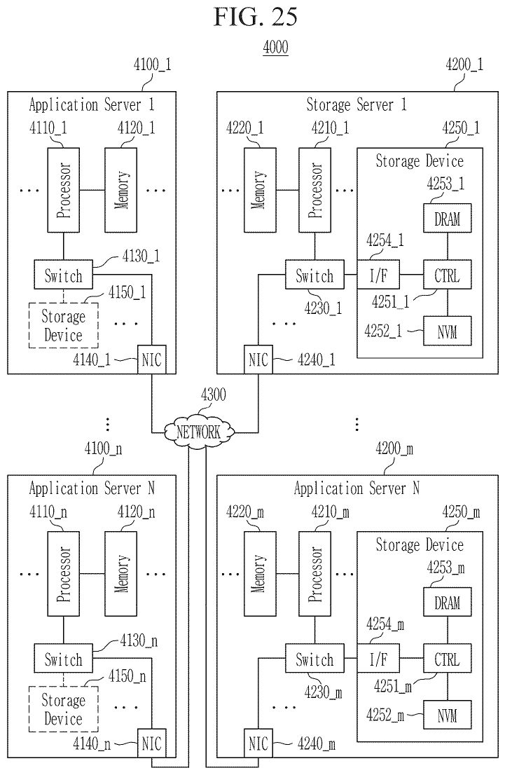

FIG. 25 is a diagram illustrating an example of a data center to which an example of a memory system is applied.

Referring to FIG. 25, a data center 4000 is a facility that collects various data and provides services, and can also be referred to as a data storage center. The data center 4000 can be a system for operating a search engine and database, and can be a computing system used by a company such as a bank or a government agency.

The data center 4000 can include application servers 4100_1 to 4100_n and storage servers 4200_1 to 4200_m. The number of application servers 4100_1 to 4100_n and the number of storage servers 4200_1 to 4200_m can be variously selected depending on the implementation, and the number of application servers 4100_1 to 4100_n and the number of storage servers 4200_1 to 4200_m can be different from each other.

The application server 4100 or storage server 4200 can include at least one of a processor 4110, 4210 and a memory 4120, 4220. Taking the storage server 4200 as an example, the processor 4210 can control the overall operation of the storage server 4200 and access the memory 4220 to execute commands and/or data loaded into the memory 4220. The memory 4220 can be DDR SDRAM Double Data Rate Synchronous DRAM, HBM High Bandwidth Memory, HMC Hybrid Memory Cube, DIMM Dual In-line Memory Module, Optane DIMM, and/or NVMDIMM Non-Volatile DIMM. Depending on the implementation, the number of processors 4210 and the number of memories 4220 included in the storage server 4200 can be selected in various ways.

In some implementations, the processor 4210 and memory 4220 can provide a processor-memory pair. In some implementations, the number of processors 4210 and memories 4220 can be different from each other. The processor 4210 can include a single core processor or a multi-core processor. The above description of the storage server 4200 can be similarly applied to the application server 4100. Depending on the implementation, the application server 4100 may not include a storage device 4150. The storage server 4200 can include at least one storage device 4250. The number of storage devices 4250 included in the storage server 4200 can be selected in various ways depending on the implementation.

In some implementations, the storage device 4250 can include a memory controller, a buffer chip, and a memory device, as described in FIGS. 1 through 15. The storage device 4250 can perform timing training operations between the memory controller and the buffer chip, and between the buffer chip and the memory device, based on the control of the memory controller. Through timing training operations, the storage device 4250 can provide improved SI. Specific details regarding the training movements are the same as those described with reference to FIGS. 1 to 15, and are therefore omitted below.

While this specification contains many specific implementation details, these should not be construed as limitations on the scope of any invention or on the scope of what can be claimed, but rather as descriptions of features that can be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features can be described above as acting in certain combinations, one or more features from a combination can in some cases be excised from the combination, and the combination can be directed to a subcombination or variation of a subcombination.

Although the implementations of the present invention have been described in detail above, the scope of the present invention is not limited thereto, and various modifications and improvements made by those skilled in the art using the basic concept of the present invention defined in the following claims also fall within the scope of the present invention.

What is claimed is:

1. A buffer chip connected between a memory controller and a memory device, comprising:
a first delay circuit configured to delay a data signal based on a timing training operation that is performed by the memory controller between the buffer chip and the memory device; and
a second delay circuit configured to delay a data strobe signal based on the timing training operation.

2. The buffer chip of claim 1, wherein the first delay circuit is configured to delay the data signal based on a delay time of the data strobe signal in the buffer chip.

3. The buffer chip of claim 1, wherein the first delay circuit is configured to delay the data signal based on a delay time of the data strobe signal in the memory device.

4. The buffer chip of claim 1, wherein the second delay circuit is configured to delay the data strobe signal based on a delay time of the data strobe signal in the buffer chip.

5. The buffer chip of claim 1, wherein one of the first delay circuit and the second delay circuit is configured to delay the data signal or the data strobe signal, based on one or more operating characteristics of the buffer chip and one or more operating characteristics of the memory device.

6. The buffer chip of claim 1, comprising:
a register configured to store a code value representing a timing training result between the memory controller and the buffer chip.

7. The buffer chip of claim 6, wherein the register is configured to provide the code value to the memory controller based on a read command of the memory controller.

8. A memory system comprising:
a memory device;
a memory controller configured to output a data signal and a data strobe signal; and
a buffer chip connected between the memory controller and the memory device,
wherein the memory controller is configured to:
control a training operation for the buffer chip, and
based on controlling the training operation for the buffer chip, (i) align the data signal and the data strobe signal that are transmitted from the memory controller to the buffer chip, and (ii) align the data signal and the data strobe signal that are transmitted from the buffer chip to the memory device.

9. The memory system of claim 8, wherein the buffer chip includes a first delay circuit configured to delay the data signal and a second delay circuit configured to delay the data strobe signal, based on a control of the memory controller.

10. The memory system of claim 9, wherein the first delay circuit is configured to delay the data signal based on a delay time of the data strobe signal in the buffer chip.

11. The memory system of claim 9, wherein the first delay circuit is configured to delay the data signal based on a delay time of the data strobe signal in the memory device.

12. The memory system of claim 9, wherein the second delay circuit is configured to delay the data strobe signal based on a delay time of the data strobe signal in the buffer chip.

13. The memory system of claim 9, wherein the memory controller includes a third delay circuit configured to delay the data signal, and
wherein the third delay circuit is configured to delay the data signal and align the data signal and the data strobe signal that are transmitted from the memory controller to the buffer chip.

14. The memory system of claim 9, wherein the buffer chip includes a register configured to store a code value representing a timing training result between the memory controller and the buffer chip.

15. The memory system of claim 9, wherein the first delay circuit is configured to, based on the buffer chip introducing less delay than the memory device, delay the data signal by a difference between a delay time of the data strobe signal in the buffer chip and a delay time of the data strobe signal in the memory device.

16. The memory system of claim 9, wherein the second delay circuit is configured to, based on the buffer chip introducing more delay than the memory device, delay the data strobe signal by a difference between a delay time of the data strobe signal in the buffer chip and a delay time of the data strobe signal in the memory device.

17. The memory system of claim 9, wherein a data strobe signal input to the second delay circuit is input through a delay path of the buffer chip, and
wherein the first delay circuit is configured to delay the data signal by a delay time of the data strobe signal in the memory device.

18. The memory system of claim 8, wherein the memory controller is configured to:
perform a first timing training operation between the buffer chip and the memory controller, and
after performing the first timing training operation, perform a second timing training operation between the buffer chip and the memory device.

19. The memory system of claim 18, wherein the buffer chip is configured to operate in a bypass mode during the second timing training operation between the buffer chip and the memory device.

20. A method for operating a memory system including a memory controller, a buffer chip, and a memory device, comprising:
performing, by the memory controller, a first timing training operation on a first data signal and a first data strobe signal that are transmitted from the memory controller to the buffer chip; and
performing, by the memory controller, a second timing training operation on a second data signal and a second data strobe signal that are transmitted from the buffer chip to the memory device, based on a delay time of the second data strobe signal in the buffer chip and a delay time of the second data strobe signal in the memory device.
